(19) United States
(12) Patent Application Publication
(10) Pub. No.: US 2015/0253639 A1
(43) Pub. Date: Sep. 10, 2015

(54) Array Substrate and LCD Panel

(71) Applicant: Shenzhen China Star Optoelectronics Technology Co. Ltd., Shenzhen (CN)

(72) Inventor: Dongzi Gao, Shenzhen (CN)

(73) Assignee: Shenzhen China Star Optoelectronics Technology Co., Ltd., Shenzhen (CN)

(21) Appl. No.: 14/362,979

(22) PCT Filed: Apr. 11, 2014
(86) PCT No.: PCT/CN2014/075128

§ 371 Date: Jun. 5, 2014

(30) Foreign Application Priority Data
Mar. 10, 2014 (CN) 201410085786.1

(51) Int. Cl. G02F 1/1362; H01L 27/02; H01L 27/12; G02F 1/1368; G02F 1/1335

(52) U.S. Cl. CPC G02F 1/136286; G02F 1/1368; G02F 1/133514; G02F 1/136277; H01L 27/124; H01L 27/0251

(57) ABSTRACT

An array substrate includes scan lines; data lines; common lines crossing among the scan lines parallelly and intersecting with the data lines, each common line coupled to a common main line outside a pixel area constructed by the pixel units; and the common main line, set up at another side of periphery of the pixel area opposite to the side which the scan lines extending to a periphery of the pixel area. The array substrate whose arrangement that a common main line opposite to scan lines extending to the periphery of pixel area prevents from a short circuit between a common main line and scan lines caused by ESD penetration at an intersection between the common main line and the scan lines, and the arrangement that the common main line and the common lines at the same surface avoids open circuit between the common main line and the common lines.

### BACKGROUND OF THE INVENTION

1. Field of the Invention The present invention relates to a liquid crystal display (LCD) technology field, more particularly, to an array substrate and an LCD panel comprising the array substrate.

2. Description of the Prior Art

With technology is flourishing, it meets demands for public by various information products. Most displays in the prior art are Cathode Ray Tube (CRT) display. Owing to faults like huge bulk, tremendous energy-consumption and long-time radiation, it damages user's health. Therefore, it gradually replaces a CRT display with an LCD.

LCD has been broadly applied for numerous advantages, such as slimness, energy-saving and non-radiation. Most of LCDs in markets are backlight LCDs comprising an LCD panel and a backlight module. Working principles of an LCD panel for generating images are that refracting light from the backlight module by replacing liquid crystal molecules between an array substrate and a color filter in parallel with each other, and controlling the direction of the liquid crystal molecules by applying a voltage between the array substrate and the color filter.

Please refer to FIG. 1 and FIG. 2. FIG. 1 and FIG. 2 are array substrates in the prior art, comprising a plurality of scan lines 10, a plurality of data lines 20, a plurality of common lines 320 and a common main line 310. Scan lines 10 and data lines 20 intersects to form a plurality of pixel units 510, and the plurality of the pixel units 510 form a pixel area 50. The common lines 320 parallelly cross among the scan lines 10 and intersect with the data lines 20 in insulation.

Refer to FIG. 1, each of the pixel units 510 comprises a transistor 40, a pixel electrode 511 and a common electrode 321. The transistor 40 comprises a gate, a semiconductor layer 410, a source 420 and a drain 430. The scan lines 10 are the gate of the transistor 40 and used for providing scan signals to each transistor 40. The semi-conductor layer 410 is set up on the gate. The source 420 on the semi-conductor layer 410 extends from one of the data lines 20 and is used for receiving data signals transmitted by the data lines 20. The drain 430 locates on the semi-conductor layer 410 and one side of which is parallel to the source 420. The pixel electrode 511 is set up in the pixel unit 510 and coupled to the drain 430 of the transistor 40. The common electrode 321 overlaps the pixel electrode 511 and is coupled to the common lines 320.

Refer to FIG. 2, to provide signals to the pixel area 50, the scan lines 10 extend to the periphery of the pixel area 50 to couple with a scan signal source, and the data lines 20 also extend to the periphery of the pixel area 50 to couple with a data signal source. Correspondingly, the common lines 320 extend to the periphery of the pixel area 50 to couple with the common main line 310 and are used for coupling with a common signal source. The common main line 310 and the scan lines 10 extending to the periphery of the pixel area 50 are set up at the identical side of the periphery of the pixel area 50. To conveniently route, the common main line 310 is perpendicular to the common lines 320. Therefore, it is necessary to arrange the common main line 310 intersecting with the scan lines 10 in insulation, and in the meantime, the common main line 310 is coupled to the common lines 320 through a hole. In such panel processing procedure, however, it is inevitable to draw into dust particles to easily attribute to Electro-Static discharge (ESD) at the intersection between the common main line 310 and the scan lines 10 and in the hole connection between the common main line 310 and the common lines 320. Furthermore, processes such as depositing, photoetching, etching, lifting off and washing, all lead to ESD. In hence, it causes a short circuit at the intersection between the common main line 310 and the scan lines 10 and in the hole connection between the common main line 310 and the common lines 320 to display abnormally. Therefore, it deteriorates quality of an LCD panel.

### SUMMARY OF THE INVENTION

To solve the technical problem in the prior art, an object of the present invention is to provide an array substrate capable of effectively preventing from ESD and an LCD panel comprising the array substrate.

According to the present invention, an array substrate comprises: a plurality of scan lines; a plurality of data lines, a plurality of pixel units formed by intersections between the plurality of scan lines and the plurality of data lines; a plurality of common lines crossing among the plurality of scan lines parallelly and intersecting with the plurality of data lines, each of the common lines being coupled to a common main line outside a pixel area constructed by the pixel units; and the common main line, set up at another side of periphery of the pixel area opposite to the side which the scan lines extending to a periphery of the pixel area.

In one aspect of the present invention, a conductive electrode is set up at the most outward side of the common main line. In another aspect of the present invention, the common main line and the common lines are at the same surface.

In another aspect of the present invention, the common main line and the common lines are at the same surface.

In another aspect of the present invention, the data lines, the common lines and the scan lines are insulated with each other at intersections.

In another aspect of the present invention, the common main line is perpendicular to the common lines.

In another aspect of the present invention, each of the pixel units comprises a transistor, a pixel electrode and a common electrode.

In still another aspect of the present invention, the transistor comprise a gate, a semiconductor layer, a source and a drain, the gate is the scan line, the semiconductor layer is on the gate, the source extends from one of the scan lines and locates on the semiconductor layer, and the drain is on the semiconductor layer.

In yet another aspect of the present invention, the drain is coupled to the pixel electrode.

According to the present invention, a liquid crystal display (LCD) panel comprises an array substrate as illustrated above, a color filter substrate, and a liquid crystal layer sandwiched between the array substrate and the color filter substrate.

In one aspect of the present invention, a conductive electrode is set up at the most outward side of the common main line.

In another aspect of the present invention, the common main line and the common lines are at the same surface.

In another aspect of the present invention, the common main line and the common lines are at the same surface.

In another aspect of the present invention, the data lines, the common lines and the scan lines are insulated with each other at intersections.

In another aspect of the present invention, the common main line is perpendicular to the common lines.

In another aspect of the present invention, each of the pixel units comprises a transistor, a pixel electrode and a common electrode.

In still another aspect of the present invention, the transistor comprise a gate, a semiconductor layer, a source and a drain, the gate is the scan line, the semiconductor layer is on the gate, the source extends from one of the scan lines and locates on the semiconductor layer, and the drain is on the semiconductor layer.

In yet another aspect of the present invention, the drain is coupled to the pixel electrode.

The present invention provides an array substrate and an LCD panel whose arrangement that a common main line opposite to scan lines extending to the periphery of pixel area prevents from a short circuit between a common main line and scan lines caused by ESD penetration at an intersection between the common main line and the scan lines, and the arrangement that the common main line and the common lines at the same surface avoids open circuit between the common main line and the common lines. In addition, such route is easier to simplify process.

### BRIEF DESCRIPTION OF THE DRAWINGS

FIG. 1 shows a structure diagram of a conventional pixel unit.

FIG. 2 shows a structure diagram of an array substrate having a pixel unit as shown in FIG. 1.

FIG. 3 shows a structure diagram of a pixel unit according to a preferred embodiment of the present invention.

FIG. 4 shows a structure diagram of an array substrate having a pixel unit as shown in FIG. 3.

FIG. 5 shows a structure diagram of an LCD panel according to a preferred embodiment of the present invention.

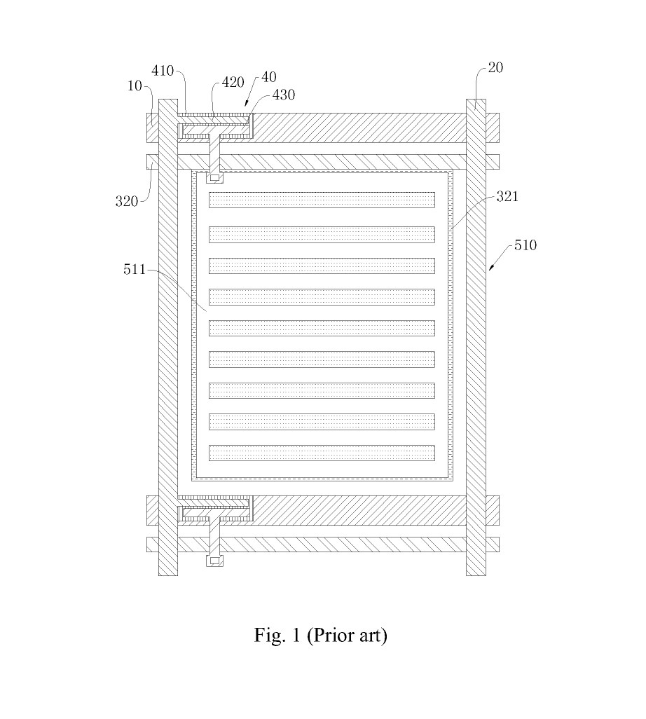

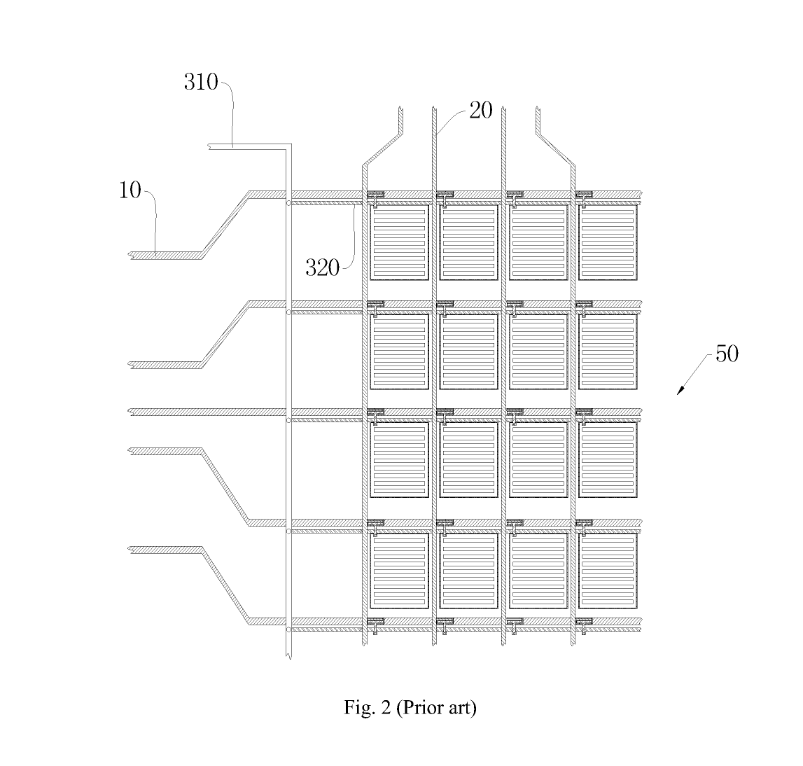

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention. In order to illustrate the technique and effects of the present invention, a detailed description will be disclosed by the following disclosure in conjunction with figures. Please note, the same components are labeled by the same number.

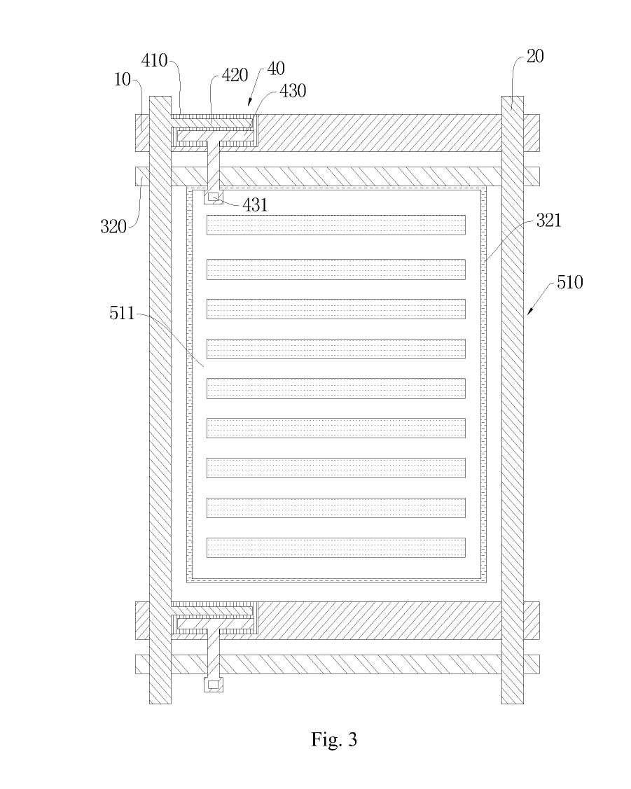

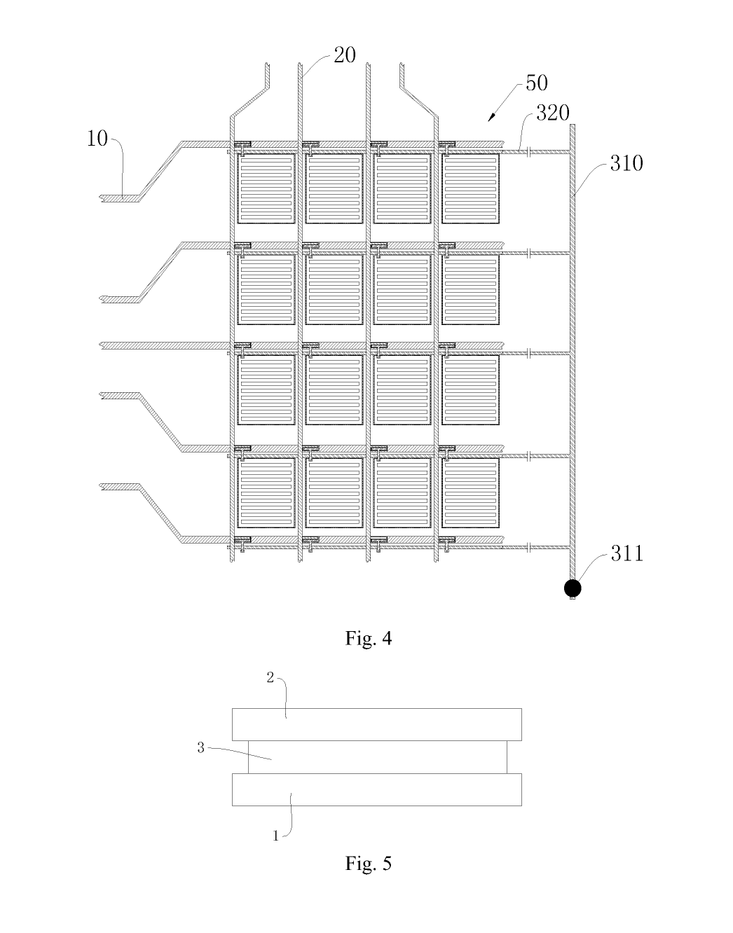

Please refer to FIG. 3 and FIG. 4. An array substrate of the embodiment comprises a plurality of scan lines 10, a plurality of data lines 20, a plurality of common lines 320. The scan lines 10 and the data lines 20 intersect with each other in insulation to form a plurality of pixel units 510, and the plurality of the pixel units 510 form a pixel area 50. The common lines 320 parallelly cross among the scan lines 10 and intersect with the data lines 20 in insulation.

Refer to FIG. 3, the pixel units 510 comprises a transistor 40, a pixel electrode 511 and a common electrode 321. The transistor 40 comprises a gate, a semi-conductor layer 410, a source 420 and a drain 430. The scan lines 10 are the gate of the transistor 40 and used for providing scan signals to each transistor 40. The semi-conductor layer 410 is set up on the gate. The source 420 on the semi-conductor layer 410 extends from one of the data lines 20 and is used for receiving data signals transmitted by the data lines 20. The drain 430 locates on the semi-conductor layer 410 and one side of which is parallel to the source 420. The pixel electrode 511 is set up in the pixel unit 510 and coupled to the drain 430 of the transistor 40. In the embodiment, the pixel electrode 511 is coupled to the drain 430 of the transistor 40 through a hole 431 because the pixel electrode 511 and the drain 430 of the transistor 40 are not at the same surface. The common electrode 321 overlaps the pixel electrode 511 and is coupled to the common lines 320. Please refer to FIG. 4. To provide signals to the pixel area 50, the array substrate further comprises a common main line 310 set up at the periphery of the pixel area 50 and coupled to a common signal source. The common lines 320, extending to the periphery of the pixel area 50 and coupled to the common main line 310, is used for transmitting common signals to each common electrode 321. In the preferred embodiment, the common main line 310 is perpendicular to the common lines 320. Correspondingly, the scan lines 10 extending to the periphery of the pixel area 50 are coupled to scan signal sources. The common main line 310 and the scan lines 10 extending to the periphery of the pixel area 50 are respectively arranged at two opposite sides of the periphery of the pixel area 50. The common main line 310 and the data lines 20 extending to the periphery of the pixel area 50 are arranged at two adjacent sides of the periphery of the pixel area 50. The common main line 310, the common lines 320 and the scan lines 10 are at the same surface but not identical to the data lines 20. Therefore, the common main line 310 is coupled to the common lines 320 directly without holes. In the meantime, it needs no crossover between the common main line 310 and the scan lines 10 to decrease possibility of ESD so that it prevents from not only a short circuit between the common line and the scan lines caused by ESD penetration but a open circuit between the common main line and the common lines resulted from ESD.

Moreover, a conductive electrode 311 is set up at the most outward side of the common main line 310 and is used for transmitting common signals to a color filter by being coupled to a transparent electrode on the color filter in a color filter substrate in parallel to the array substrate.

Please refer to FIG. 5, the present invention further provides an LCD panel comprising the above-mentioned arrays substrate 1, the color filter substrate 2 and a liquid crystal layer 3 between the array substrate 1 and the color filter substrate 2. The conductive electrode 311 on the common main line 310 transmits common signals to the color filter by being coupled to an transparent electrode on the color filter in the color filter substrate in parallel to the array substrate. The liquid crystal layer 3 comprises a plurality of liquid crystal molecules and the color filter substrate 2 in opposite to the array substrate 1. The color filter substrate 2 generally comprises a transparent substrate (e.g. a glass substrate) and a black matrix, chromatic photoresist layers (e.g. red, green, blue color filter patterns) and an alignment layer, etc. Given that the color filter substrate 2 in the present invention is identical to the color filter substrate in the prior art, the detailed structure of the color filter substrate 2 is referred to relatively conventional techniques, there is no further description therefore.

In conclusion, the present invention provides an array substrate and an LCD panel whose arrangement that a common main line opposite to scan lines extending to the periphery of pixel area prevents from a short circuit between a common main line and scan lines caused by ESD penetration at an intersection between the common main line and the scan lines, and the arrangement that the common main line and the common lines at the same surface avoids open circuit between the common main line and the common lines. In addition, such route is easier to simplify process.

The terms “a” or “an”, as used herein, are defined as one or more than one. The term “another”, as used herein, is defined as at least a second or more. The terms “including” and/or “having” as used herein, are defined as comprising. It should be noted that if it is described in the specification that one component is “connected,” “coupled” or “joined” to another component, a third component may be “connected,” “coupled,” and “joined” between the first and second components, although the first component may be directly connected, coupled or joined to the second component.

Although the present invention has been explained by the embodiments shown in the drawings described above, it should be understood to the ordinary skilled person in the art that the invention is not limited to the embodiments, but rather various changes or modifications thereof are possible without departing from the spirit of the invention. Accordingly, the scope of the invention shall be determined only by the appended claims and their equivalents.

What is claimed is:

1. An array substrate comprising:
a plurality of scan lines;
a plurality of data lines, a plurality of pixel units formed by intersections between the plurality of scan lines and the plurality of data lines;
a plurality of common lines crossing among the plurality of scan lines parallelly and intersecting with the plurality of data lines, each of the common lines being coupled to a common main line outside a pixel area constructed by the pixel units; and
the common main line, set up at another side of periphery of the pixel area opposite to the side which the scan lines extending to a periphery of the pixel area.

2. The array substrate of claim 1, wherein a conductive electrode is set up at the most outward side of the common main line.

3. The array substrate of claim 2, wherein the common main line and the common lines are at the same surface.

4. The array substrate of claim 1, wherein the common main line and the common lines are at the same surface.

5. The array substrate of claim 4, wherein the data lines, the common lines and the scan lines are insulated with each other at intersections.

6. The array substrate of claim 4 wherein the common main line is perpendicular to the common lines.

7. The array substrate of claim 1, wherein each of the pixel units comprises a transistor, a pixel electrode and a common electrode.

8. The array substrate of claim 7, wherein the transistor comprise a gate, a semiconductor layer, a source and a drain, the gate is the scan line, the semiconductor layer is on the gate, the source extends from one of the scan lines and locates on the semiconductor layer, and the drain is on the semiconductor layer.

9. The array substrate of claim 8, wherein the drain is coupled to the pixel electrode.

10. An liquid crystal display (LCD) panel, comprising an array substrate as claimed in claim 1, a color filter substrate, and a liquid crystal layer sandwiched between the array substrate and the color filter substrate.

11. The LCD panel of claim 10, wherein a conductive electrode is set up at the most outward side of the common main line.

12. The LCD panel of claim 11, wherein the common main line and the common lines are at the same surface.

13. The LCD panel of claim 10, wherein the common main line and the common lines are at the same surface.

14. The LCD panel of claim 13, wherein the data lines, the common lines and the scan lines are insulated with each other at intersections.

15. The LCD panel of claim 13, wherein the common main line is perpendicular to the common lines.

16. The LCD panel of claim 10, wherein each of the pixel units comprises a transistor, a pixel electrode and a common electrode.

17. The LCD panel of claim 16, wherein the transistor comprise a gate, a semiconductor layer, a source and a drain, the gate is the scan line, the semiconductor layer is on the gate, the source extends from one of the scan lines and locates on the semiconductor layer, and the drain is on the semiconductor layer.

18. The LCD panel of claim 17, wherein the drain is coupled to the pixel electrode.
